(19) United States
(12) Patent Application Publication
(10) Pub. No.: US 2024/0109768 A1
(43) Pub. Date: Apr. 4, 2024

(54) SENSOR DEVICE PACKAGE AND METHOD FOR MANUFACTURING THE SAME

(71) Applicant: Advanced Semiconductor Engineering, Inc., Kaohsiung (TW)

(72) Inventors: Chieh-An YEH, Kaohsiung (TW); Tai-Hung KUO, Kaohsiung (TW)

(73) Assignee: Advanced Semiconductor Engineering, Inc., Kaohsiung (TW)

(21) Appl. No.: 18/536,010

(22) Filed: Dec. 11, 2023

Related U.S. Application Data
(63) Continuation of application No. 16/783,914, filed on Feb. 6, 2020.

(51) Int. Cl. B81B 7/00; B81C 1/00; G01D 11/24

(52) U.S. Cl. CPC B81B 7/0058; B81C 1/00904; G01D 11/245; B81B 2207/012; B81B 2207/098

(57) ABSTRACT

A sensor device package and method of manufacturing the same are provided. The sensor device package includes a carrier, a sensor component, an encapsulation layer and a protection film. The sensor component is disposed on the carrier, and the sensor component includes an upper surface and edges. The encapsulation layer is disposed on the carrier and encapsulates the edges of the sensor component. The protection film covers at least a portion of the upper surface of the sensor component.

### CROSS-REFERENCE TO RELATED APPLICATION

This application is a continuation of U.S. patent application Ser. No. 16/783,914 filed Feb. 6, 2020, the content of which is incorporated herein by reference in its entirety.

### BACKGROUND

### 1. Technical Field

The present disclosure relates to a micro electro-mechanical system (MEMS) device package and method for manufacturing the same, and more particularly, to a sensor device package and method for manufacturing the same.

### 2. Description of the Related Art

As technology advances, micro electro-mechanical system (MEMS) devices have been broadly integrated into mobile communication products such as smart phones. The MEMS device package normally includes mechanical structure or vent holes, and residues such as glue or cleaning solvent tends to adhere to the mechanical structure or vent holes. Accordingly, The MEMS devices suffer from low yield and reliability due to residue issues.

### SUMMARY

In some embodiments, a sensor device package includes a carrier, a sensor component, an encapsulation layer and a protection film. The sensor component is disposed on the carrier, and the sensor component includes an upper surface and edges. The encapsulation layer is disposed on the carrier and encapsulates the edges of the sensor component. The protection film covers at least a portion of the upper surface of the sensor component.

In some embodiments, a method of manufacturing a sensor device package includes the following operations. A plurality of sensor components supported by a carrier substrate are provided. A protection film is formed to at least partially cover upper surfaces of the sensor components. The carrier substrate is attached to a tape. The carrier substrate is sawed into a plurality of carriers. The sensor components and the carriers are released from the tape.

In some embodiments, a method of manufacturing a sensor device package includes the following operations. A plurality of sensor components supported by a carrier substrate are provided. Upper surfaces of the sensor components are attached to a platform with a double-sided tape. A first side of the double-sided tape is adhered to the sensor components and covers media ports of the sensor components, and a second side of the double-sided tape is adhered to the platform. The carrier substrate is sawed into a plurality of carriers under a non-vacuum circumstance. The double-sided tape is cured to remove adhesions of the first side and the second side of the double-sided tape to release the sensor components and the carriers from the double-sided tape.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a schematic top view of a sensor device package in accordance with some embodiments of the present disclosure.

FIG. 1A is a schematic cross-sectional view of a sensor device package taken in a line A-A′ in FIG. 1.

FIG. 2 is a schematic cross-sectional view of a sensor device package in accordance with some embodiments of the present disclosure.

FIG. 3 is a schematic cross-sectional view of a sensor device package in accordance with some embodiments of the present disclosure.

FIG. 4A, FIG. 4B, FIG. 4C, FIG. 4D and FIG. 4E illustrate operations of manufacturing a sensor device package in accordance with some embodiments of the present disclosure.

FIG. 5A, FIG. 5B and FIG. 5C illustrate operations of manufacturing a sensor device package in accordance with some embodiments of the present disclosure.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatially relative terms, such as “beneath,” “below,” “above,” “over,” “on,” “upper,” “lower,” “left,” “right,” “vertical,” “horizontal,” “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

Some embodiments of the present disclosure provide a sensor device package with a protection film. The protection film covers at least a portion of an upper surface of a sensor component. The protection film protects the sensor component from being damaged by residues such as glue residue used during fabrication, debris, particles, dust or the like, or prevents liquid such as wafer or cleaning solvent used in singulation from entering the sensor component. The protection film may also be configured as a buffering adhesion layer to provide cushion and/or adhesion for the sensor component during fabrication and operation. Consequently, yield and reliability of the sensor device package can be improved. The protection film is such configured that the operation of the sensor device package is not affected. By way of examples, the protection film can be waterproof, gas-permeable, light-permeable, light-shielding and/or wave-transmissible.

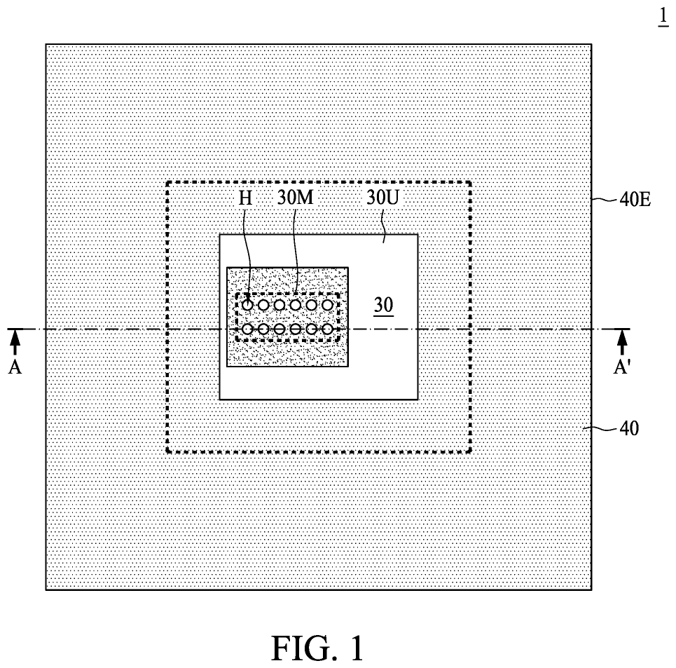

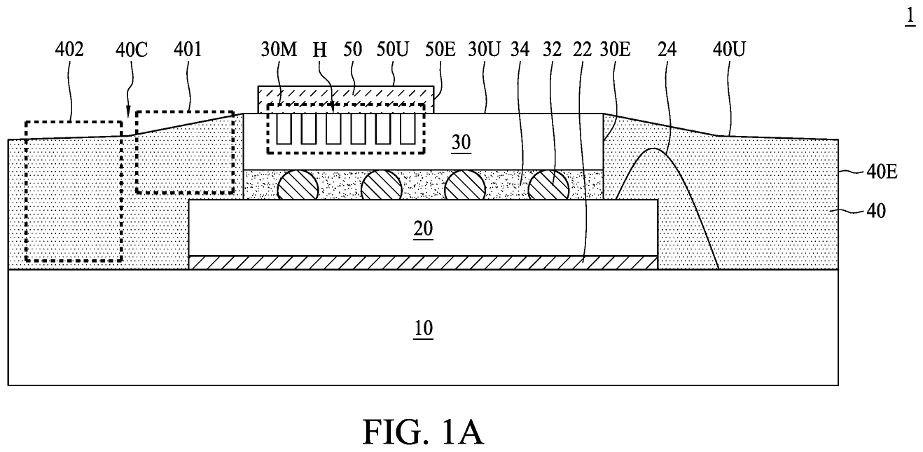

FIG. 1 is a schematic top view of a sensor device package 1 in accordance with some embodiments of the present disclosure, and FIG. 1A is a schematic cross-sectional view of a sensor device package 1 taken in a line A-A′ in FIG. 1. For the purpose of clarity, some components may not be shown in FIG. 1 and FIG. 1A. As shown in FIG. 1 and FIG. 1A, the sensor device package 1 includes a carrier 10, a sensor component 30, an encapsulation layer 40 and a protection film 50. The carrier 10 may include, but is not limited to, a substrate such as a package substrate with embedded circuitry. The carrier 10 may include any types of conductive carriers or insulative carriers. By way of examples, the carrier 10 may include an interposer, a fan-out circuit layer, a redistribution layer (RDL), a semiconductor die, a lead frame or the like.

The sensor component 30 is disposed on the carrier 10. The sensor component 30 includes an upper surface 30U and edges 30E. The encapsulation layer 40 is disposed on the carrier 10, and encapsulates the edges 30E of the sensor component 30. The encapsulation layer 40 may partially or fully cover the edges 30E of the sensor component 30. The encapsulation layer 40 may expose the upper surface 30U or partially cover the upper surface 30U of the sensor component 30. The encapsulation layer 40 may include a molding material such as epoxy-based material (e.g. FR4), resin-based material (e.g. Bismaleimide-Triazine (BT)), Polypropylene (PP)), molding compound or other suitable materials. The encapsulation layer 40 may further include fillers such as silicon oxide fillers dispensed in the molding material, or may be substantially filler-free. The protection film 50 may cover at least a portion of the upper surface 30U of the sensor component 30.

The encapsulation layer 40 includes an upper surface 40U and edges 40E. In some embodiments, the upper surface 40U of the encapsulation layer 40 is lower than or equal to the upper surface 30U of the sensor component 30. In some embodiments, the upper surface 40U of the encapsulation layer 40 may include a substantially flat surface. In some other embodiments, the encapsulation layer 40 may include a first portion 401 adjacent to the sensor component 30, and a second portion 402 distal to the sensor component 30. The upper surface 40U of the second portion 402 may be lower than the upper surface 40U of the first portion 401, and the upper surface 40U of the encapsulation layer 40 may include a concave surface 40C.

In some embodiments, the sensor device package 1 may further include an electronic component 20 disposed between the carrier 10 and the sensor component 30, and encapsulated by the encapsulation layer 40. The electronic component 20 may include an active electronic component such as an application specific integrated circuit (ASIC) or a semiconductor die, a passive electronic component or a combination thereof. In some embodiments, the electronic component 20 is adhered to the carrier 10 with an adhesive film 22 such as a die attach film (DAF). The carrier 10, the electronic component 20 and the sensor component 30 may be electrically connected. In some embodiments, the sensor device package 1 may further include a plurality of conductive structures 32 disposed between the sensor component 30 and the electronic component 20, and electrically the sensor component 30 to the electronic component 20. Accordingly, the electronic component 20 can control the sensor component 30, and receive and process signals sensed by the sensor component 30. The conductive structures 32 may include conductive bumps such as solder bumps, conductive pillars such as copper pillars, or other suitable conductive structures. In some other embodiments, the conductive structures 32 may be omitted, and the sensor component 30 and the electronic component 20 may be electrically connected in different manners such as by wire bonding.

In some embodiments, an underfill 34 may be disposed between the electronic component 20 and the sensor component 30 to protect the conductive structures 32. In some embodiments, the underfill 34 may be omitted, and the conductive structures 32 may be encapsulated by the encapsulation layer 40. In some embodiments, at least an edge 20E of the electronic component 20 may laterally protrude out from the respective edge 30E of the sensor component 30. The sensor device package 1 may further include a plurality of bonding wires 24 electrically connecting the electronic component 20 to the carrier 10. The bonding wires 24 may be encapsulated by the encapsulation layer 40. In some other embodiments, the bonding wires 24 may be omitted, and the electronic component 20 and the carrier 10 may be electrically connected in different manners.

In some embodiments, the sensor device package 1 may further include a circuit board such as a printed circuit board (PCB) disposed under the carrier 10 and electrically connected to the electronic component 20 and the sensor component 30 through the carrier 10 to create external connection for the electronic component 20 and the sensor component 30.

In some embodiments, the sensor component 30 may include a MEMS component. Examples of the MEMS component may include a motion sensor such as an acceleration sensor, a magnetometer or a gyro sensor, an ambient sensor such as a temperature sensor, a barometric pressure sensor, a gas sensor or an acoustic microphone, and a biomedical sensor such as a pulse sensor, a blood pressure sensor or blood glucose sensor. In some embodiments, the sensor component 30 includes a media port 30M. The media port 30M may be configured to be in direct or indirect communication with the environment or an external electronic component. In some embodiments, the media port 30M may include a plurality of vent holes H recessed from the upper surface 30U of the sensor component 30. In some embodiments, the vent holes H expose sensing element such as diaphragm or the like embedded in the sensor component 30, and do not penetrate through the sensor component 30.

In some embodiments, the protection film 50 may locally cover the upper surface 30U of the sensor component 30. The protection film 50 may cover 50%, 60%, 70%, 80% or more of the upper surface 30U. In some embodiments, the protection film 50 at least covers the media port 30M of the sensor component 30. The protection film 50 may cover the media port 30M and expose the other portion of the upper surface 30U such that the cost of the protection film 50 can be reduced. In addition, the edges 50E of the protection film 50 may be away from the edges 30E of the sensor component 30, and thus delamination of the protection film 50 may be reduced. The upper surface 50U of the protection film 50 may include a substantially flat surface, or a rough surface. The protection film 50 can help to keep residues or liquid from entering the vent holes H of the media port 30M such that the reliability and yield can be improved. In some embodiments, the protection film 50 may include a waterproof and gas-permeable film. The waterproof function of the protection film 50 may help to keep liquid such as water or moisture from entering the vent holes H of the media port 30M. In some embodiments, the protection film 50 is hydrophobic. When liquid such as water or cleaning solvent drops on the hydrophobic upper surface 50U, the contact angle between water and the upper surface 50U is larger than 90 degrees. Accordingly, the hydrophobicity can expel water from the protection film 50 to enhance waterproof ability. The protection film 50 may include a hydrophobic material. By way of example, the hydrophobic material may include a fluorine-containing material such as Teflon, polytetrafluoroethylene or polychlorotrifluoroethylene, siloxane-based material such as silane, or other hydrophobic materials. The gas-permeable function on the other hand allows gases to pass the protection film 50 such that the media port 30M can be in communication with the environment to provide sensing function. In some other embodiments, the protection film 50 may include an air-tight film which does not allow gas to pass through. The protection film 50 may include a vibratable film which can transfer wave such as pressure wave, acoustic wave or the like through vibration such that the sensor component 30 can sense the wave outside the protection film 50. The protection film 50 can be formed on the upper surface 30U of the sensor component 30 by deposition such as chemical vapor deposition (CVD), lamination or other suitable methods. The protection film 50 may also be configured as a buffering adhesion layer to provide cushion and/or adhesion for the sensor component during fabrication and operation.

The sensor device packages and manufacturing methods of the present disclosure are not limited to the above-described embodiments, and may be implemented according to other embodiments. To streamline the description and for the convenience of comparison between various embodiments of the present disclosure, similar components of the following embodiments are marked with same numerals, and may not be redundantly described.

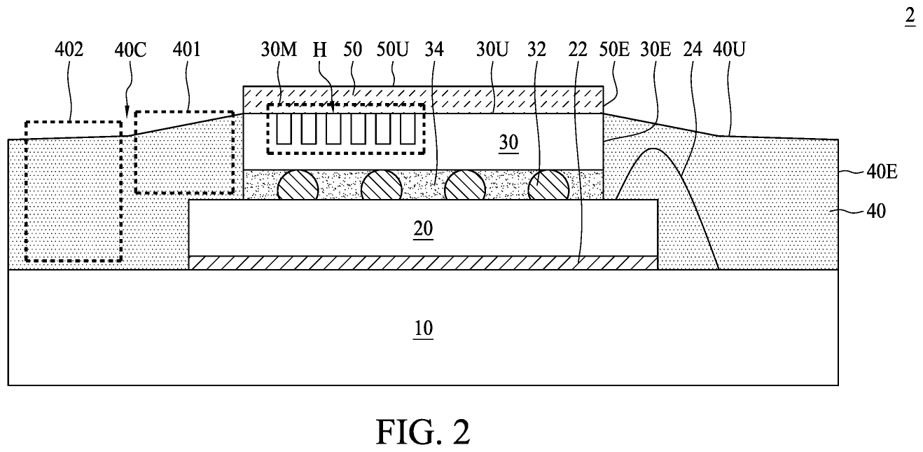

FIG. 2 is a schematic cross-sectional view of a sensor device package 2 in accordance with some embodiments of the present disclosure. As shown in FIG. 2, in contrast to the sensor device package 1, the protection film 50 may cover the media port 30M and some other portion of the upper surface 30U of the sensor component 30. By way of example, the protection film 50 may entirely covers the upper surface 30U of the sensor component 30. In some embodiments, some or all of the edges 50E of the protection film 50 may be substantially aligned with the edges 30E of sensor component 30.

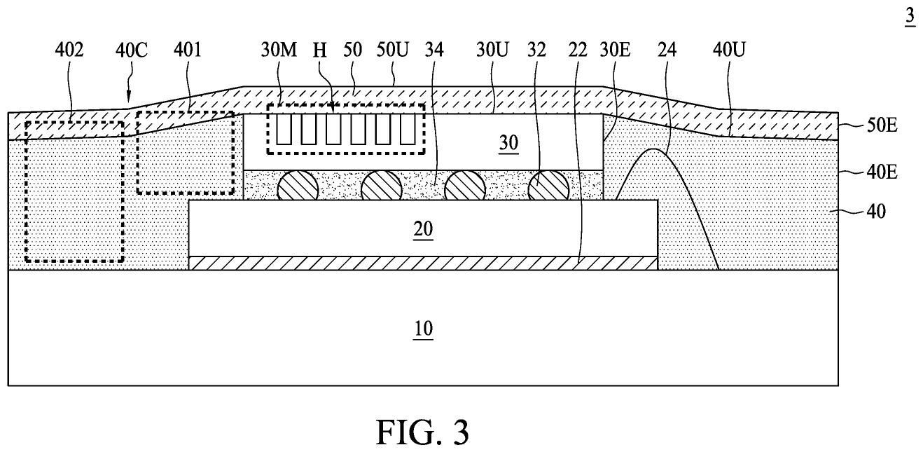

FIG. 3 is a schematic cross-sectional view of a sensor device package 3 in accordance with some embodiments of the present disclosure. As shown in FIG. 3, in contrast to the sensor device package 2, the protection film 50 may further cover the upper surface 40U of the encapsulation layer 40. In some embodiments, some or all of the edges 50E of the protection film 50 may be substantially aligned with the edges 40E of encapsulation layer 40. In some embodiments, the upper surface 40U of the encapsulation layer 40 may not be flat, and the protection film 50 may be substantially conformal with respect to the upper surface 40U to have an uneven upper surface 50U as well. In some other embodiments, the upper surface 50U of the protection film 50 may include a substantially flat surface.

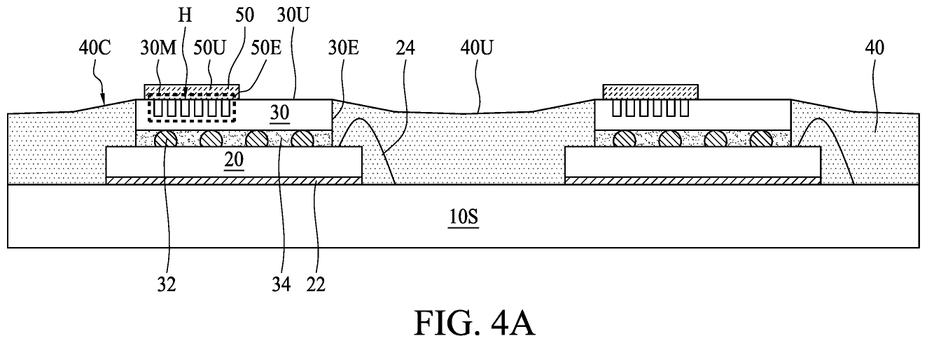

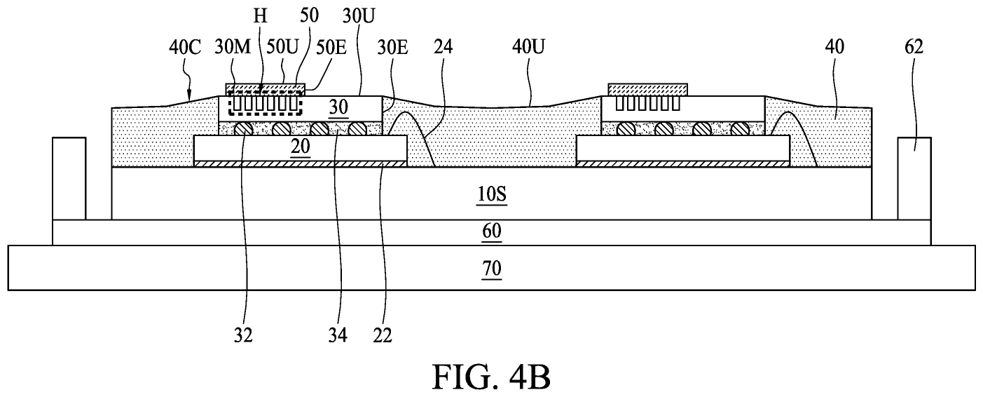

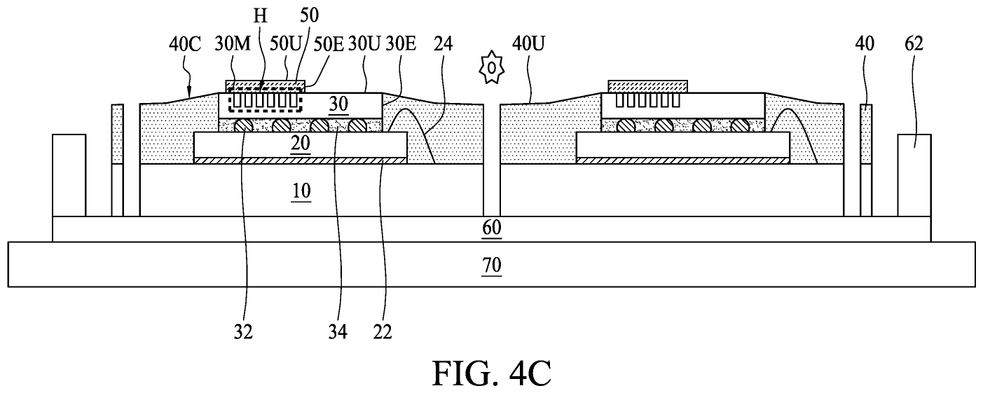

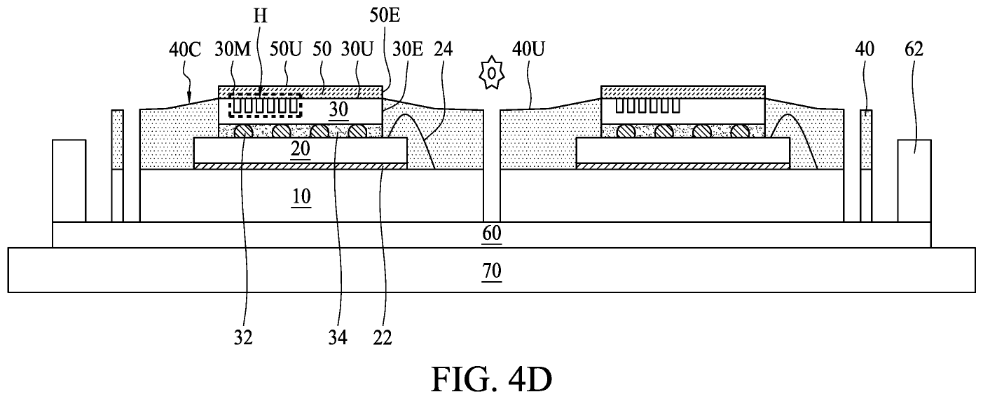

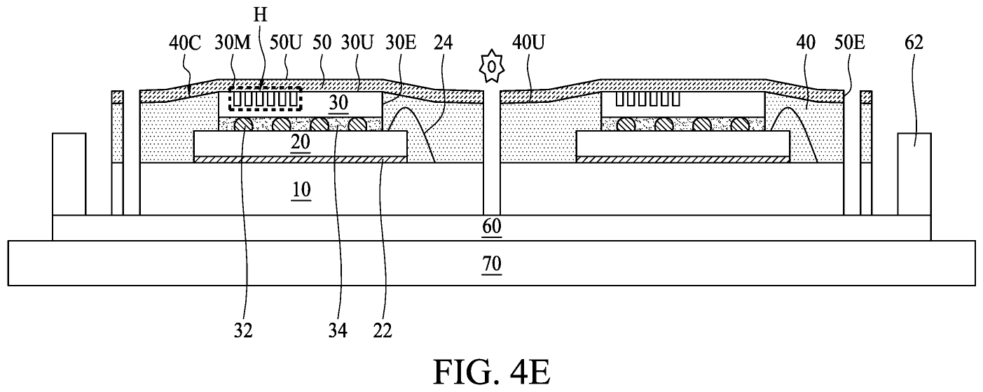

FIG. 4A, FIG. 4B, FIG. 4C, FIG. 4D and FIG. 4E illustrate operations of manufacturing a sensor device package in accordance with some embodiments of the present disclosure. As shown in FIG. 4A, a plurality of sensor components 30 supported by a carrier substrate 10S are provided. In some embodiments, each of the sensor components 30 is electrically connected to one or more electronic component 20 through conductive structures 32, and an underfill 34 may be formed between the sensor component 30 and the electronic component 20. In some embodiments, the electronic components 20 may be attached to the carrier substrate 10S with adhesive films 22, and electrically connected to the carrier substrate 10S by bonding wires 24. A protection film 50 is formed to at least partially cover an upper surface 30U of each of the sensor components 30. An encapsulation layer 40 is formed on the carrier substrate 10S to encapsulate edges 30E of the sensor components 30. The encapsulation layer 40 may include molding material and may be formed by molding, and thus the upper surface 40U of the encapsulation layer 40 may be non-flat. By way of example, the upper surface 40U of the encapsulation layer 40 may include a concave surface 40C.

In some embodiments, the encapsulation layer 40 is formed prior to forming the protection film 50. The protection film 50 may cover the media port 30M of the sensor component 30 as illustrated in FIG. 1A, may entirely cover the upper surface 30U of the sensor component 30 as illustrated in FIG. 2, or may cover the upper surface 30U of the sensor component 30 and further cover at least a portion of the encapsulation layer 40 as illustrated in FIG. 3. In some embodiments, the protection film 50 is formed subsequent to formation of the encapsulation layer 40, and thus the protection film 50 can selectively cover the upper surface 40U of the encapsulation layer 40. By way of example, the protection film 50 can be formed by chemical vapor deposition (CVD), and the protection film 50 may be conformal with respect to the upper surface 40U of the encapsulation layer 40. For example, the protection film 50 may be engaged with the concave surface 40C of the encapsulation layer 40. Accordingly, adhesion between the protection film 50 and the encapsulation layer 40 can be enhanced, and delamination of the protection film 50 in successive processes can be alleviated.

In some other embodiments, the encapsulation layer 40 is formed subsequent to forming the protection film 50. By way of example, the protection film 50 can be formed by lamination. The protection film 50 may include a pre-formed protection film laminated on the upper surface 30U of the sensor component 30. The pre-formed protection film 50 may be pressed toward the sensor component 30 to be bonded to the sensor component 30. In some embodiments, the pre-formed protection film 50 may be heated during lamination to increase adhesion. The protection film 50 may cover the media port 30M of the sensor component 30 as illustrated in FIG. 1A, or may entirely cover the upper surface 30U of the sensor component 30 as illustrated in FIG. 2. The edge 50E of the protection film 50 does not exceed the edge 30E of the sensor component 30, and thus delamination of the protection film 50 in successive processes can be alleviated.

As shown in FIG. 4B, the carrier substrate 10S is attached to a tape 60. In some embodiments, the tape 60 is supported by a frame 62, and supported by a platform 70. In some embodiments one side of the tape 60 may be bonded to the carrier substrate 10S with adhesion force, while the other side of the tape 60 may be bonded to the platform 70 with adhesion force, vacuum force or the like. In some embodiments, the tape 60 may include a UV tape, and the adhesion of the tape 60 can be reduced by irradiating the tape 60 with a UV light.

As shown in FIG. 4C, the carrier substrate 10S is sawed into a plurality of carriers 10. With the protection films 50 covering the sensor components 30, liquid such as water or cleaning solvent and residues such as particles, debris or dust are prevented from contaminating and damaging the sensor components 30. For example, liquid and residues are prevented from entering the media ports 30M of the sensor components 30. The sensor components 30 and the carriers 10 are released from the tape 60 e.g., by irradiating the tape 60 with a UV light to form the sensor device package 1 as illustrated in FIG. 0.1 and FIG. 1A.

In some other embodiments, the protection film 50 may entirely cover the upper surface 30U of the sensor component 30 as illustrated in FIG. 4D, and the sensor device package 2 as illustrated in FIG. 0.2 can be formed after singulation. In still some other embodiments, the protection film 50 may further cover the encapsulation layer 40 as illustrated in FIG. 4E, and the sensor device package 3 as illustrated in FIG. 0.3 can be formed after singulation.

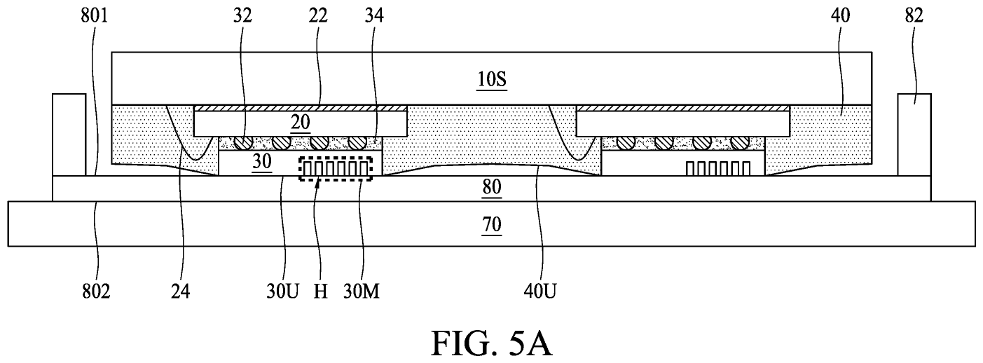

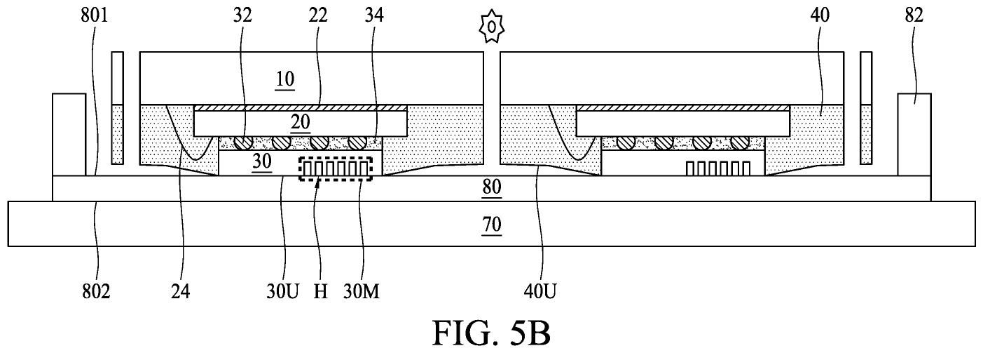

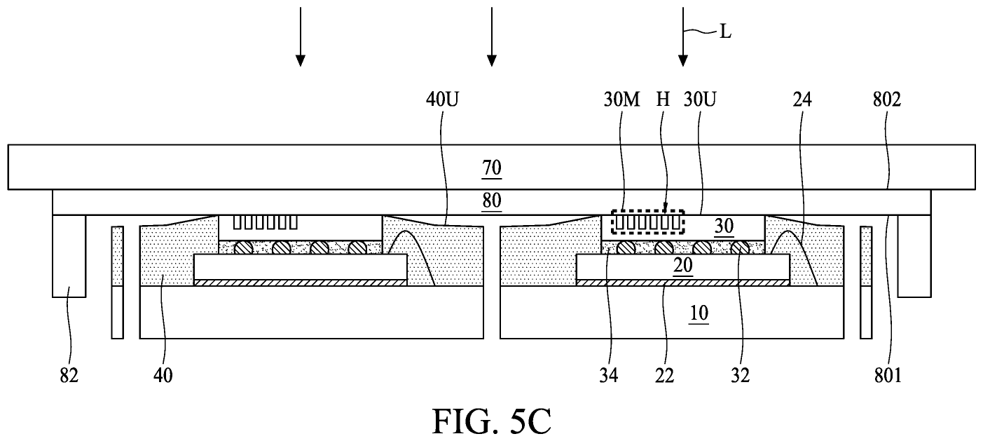

FIG. 5A, FIG. 5B and FIG. 5C illustrate operations of manufacturing a sensor device package in accordance with some embodiments of the present disclosure. As shown in FIG. 5A, a plurality of sensor components 30 supported by a carrier substrate 10S are provided. In some embodiments, each of the sensor components 30 is electrically connected to one or more electronic component 20 through conductive structures 32, and an underfill 34 may be formed between the sensor component 30 and the electronic component 20. In some embodiments, the electronic components 20 may be attached to the carrier substrate 10S with adhesive films 22, and electrically connected to the carrier substrate 10S by bonding wires 24. An encapsulation layer 40 may be formed on the carrier substrate 10S to encapsulate edges 30E of the sensor components 30. The encapsulation layer 40 may include molding material and may be formed by molding, and thus the upper surface 40U of the encapsulation layer 40 may be non-flat. By way of example, the upper surface 40U of the encapsulation layer 40 may include a concave surface 40C. The encapsulation layer 40 may expose upper surfaces 30U of the sensor components 30.

The upper surfaces 30U of the sensor components 30 are then attached to a platform 70 with a double-sided tape 80. In some embodiments, a first side 801 of the double-sided tape 80 is adhered to the sensor components 30 and covers media ports 30M of the sensor components 30, and a second side 802 of the double-sided tape 80 is adhered to the platform 70. The double-sided tape 80 may be supported by a frame 82. With the double-sided tape 80 can be fixed on the platform 70 by adhesion force, rather than vacuum force. In some embodiments, the double-sided tape 80 may include a double-sided UV tape, and the adhesion of the double-sided tape 80 on both the first side 801 and the second side 802 can be reduced by irradiating the double-sided tape 80 with a UV light.

As shown in FIG. 5B, the carrier substrate 10S is sawed into a plurality of carriers 10 under a non-vacuum circumstance. With the double-sided tape 80 covering the sensor components 30, liquid such as water or cleaning solvent and residues such as particles, debris or dust are prevented from damaging the sensor components 30. For example, liquid and residues are prevented from entering the media ports 30M of the sensor components 30. Moreover, since the upper surfaces 30U of the sensor components 30 are adhered to the platform 70 with the double-sided tape 80 rather than vacuum force, liquid and residues will not be sucked into the media ports 30M due to negative pressure or vacuum effect.

As shown in FIG. 5C, the double-sided tape 80 is cured to remove adhesions of the first side 801 and the second side 802 of the double-sided tape 80 to release the sensor components 30 and the carriers 10 from the double-sided tape 80. In some embodiments, the sensor components 30 and the carriers 10 are released from the double-sided tape 80 e.g., by irradiating the double-sided tape 80 with a UV light L to form the sensor device package.

In some embodiments of the present disclosure, a sensor device package with a protection film is provided. The protection film covers at least a portion of an upper surface of a sensor component to protect the sensor component from being damaged by residues. The protection film is such configured that the operation of the sensor device package is not affected. The protection film increases yield and reliability of the sensor device package.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A method of manufacturing an electronic package, comprising:
providing an electronic packaging structure comprising a carrier and an electronic component carried by the carrier, wherein the electronic component has a first surface and a hole exposed from the first surface;
covering the hole to space apart the hole from a space outside of the electronic packaging structure;
sawing the electronic packaging structure; and
exposing the hole to the space outside of the electronic packaging structure.

2. The method of claim 1, wherein the step of exposing the hole to the space outside of the electronic packaging structure is performed later than the step of sawing the electronic packaging structure.

3. The method of claim 2, further comprising cutting the electronic packaging structure along a direction from the carrier toward the first surface of the electronic component.

4. The method of claim 1, wherein the step of covering the hole comprises attaching a tape to the first surface of the electronic component.

5. The method of claim 4, further comprising attaching the tape to the first surface of the electronic component until the tape horizontally overlaps the hole.

6. The method of claim 5, further comprising irradiating the tape with a light.

7. The method of claim 4, wherein the step of attaching the tape comprises adhering the tape to a first portion of a first surface of the electronic packaging structure and leaving a second portion of the first surface of the electronic packaging structure not adhered by the tape.

8. The method of claim 7, further comprising cutting the electronic packaging structure at the second portion of the first surface of the electronic packaging structure.

9. The method of claim 1, further comprises encapsulating the electronic component with an encapsulation layer and adhering a tape to the first surface of the electronic component later than encapsulating.

10. The method of claim 9, further comprising adhering the tape to the encapsulation layer simultaneously with adhering the tape to the first surface of electronic component.

11. A method of manufacturing an electronic package, comprising:
providing a platform and a tape, wherein the tape has a first surface attached to the platform and a second surface opposite to the first surface;
adhering the second surface of the tape to an electronic packaging structure; and
removing a first adhesion of the first surface and a second adhesion of the second surface.

12. The method of claim 11, further comprising:
dividing the electronic packaging structure into a plurality of unit package structures; and
irradiating the plurality of unit package structures with a light simultaneously.

13. The method of claim 12, wherein irradiating the plurality of unit package structures is along a direction from the first surface of the tape toward the second surface of the tape.

14. The method of claim 12, further comprising releasing a first portion of a bottom surface of the one of the plurality of unit package structures from the tape, wherein the first portion of the bottom surface is adhered to the tape earlier, and a second portion of the bottom surface is not adhered to the tape.

15. The method of claim 14, wherein the step of irradiating the plurality of unit package structures is earlier than the step of releasing the first portion of the bottom surface of one of the plurality of unit package structures from the tape.

16. A method of manufacturing a device package, comprising:
providing an encapsulated packaging structure including:
an electronic component having an active surface and a hole exposed by the active surface; and
an encapsulation layer encapsulating the electronic component, wherein the hole is exposed by the encapsulation layer;
attaching a film to the encapsulated packaging structure until the film horizontally overlaps the hole; and
dividing the encapsulated packaging structure into a plurality of unit device packages.

17. The method of claim 16, wherein attaching the film comprises adhering the film on the active surface of the electronic component and a first surface of the encapsulation layer exposing the hole.

18. The method of claim 17, further comprising adhering the film on a concave portion of the first surface of the encapsulation layer.

19. The method of claim 17, further comprising enclosing the hole by the film.

20. The method of claim 17, wherein the film horizontally overlaps the encapsulation layer after the film is adhered.
